(19) United States
(12) Patent Application Publication
(10) Pub. No.: US 2021/0407938 A1
(43) Pub. Date: Dec. 30, 2021

(54) SEMICONDUCTOR DEVICE AND MANUFACTURING METHOD THEREOF

(71) Applicant: Kioxia Corporation, Tokyo (JP)

(72) Inventors: Akitsugu HATAZAKI, Yokkaichi (JP); Atsushi KATO, Yokkaichi (JP)

(73) Assignee: Kioxia Corporation, Tokyo (JP)

(21) Appl. No.: 17/470,379

(22) Filed: Sep. 9, 2021

Related U.S. Application Data
(63) Continuation of application No. PCT/JP2019/011275, filed on Mar. 18, 2019.

(51) Int. Cl. H01L 23/00; H01L 23/522

(52) U.S. Cl. CPC H01L 24/05; H01L 23/5226; H01L 24/80; H01L 2224/80895; H01L 2224/05124; H01L 2224/05647; H01L 2224/08145

(57) ABSTRACT

A semiconductor device comprises a first chip including a first semiconductor substrate, a first semiconductor element on the first semiconductor substrate, a first wiring layer to be connected to the first semiconductor element, and a first pad to be connected to the first wiring layer, and a second chip including a second semiconductor substrate, a second semiconductor element on the second semiconductor substrate, a second wiring layer to be connected to the second semiconductor element, and a second pad to be connected to the second wiring layer and joined to the first pad. At least one of the first pad and the second pad includes a first metal layer to be joined to the other pad, a second metal layer having a coefficient of thermal expansion higher than that of the first metal layer, and a barrier metal layer between the first metal layer and the second metal layer.

### CROSS-REFERENCE TO RELATED APPLICATIONS

This application is based upon and claims the benefit of priority from PCT Application No. PCT/JP2019/011275, filed on Mar. 18, 2019; the entire contents of which are incorporated herein by reference.

### FIELD

An embodiment of the present invention relates to a semiconductor device and a manufacturing method thereof.

### BACKGROUND

In a bonding technology for bonding semiconductor substrates to each other, for example, a semiconductor substrate having a semiconductor element such as a memory formed thereon and a semiconductor substrate having a peripheral circuit of the semiconductor element formed thereon are bonded to each other. At the time of the bonding, pads of the respective substrates are joined to one another.

### BRIEF DESCRIPTION OF THE DRAWINGS

FIG. 1 is a sectional view illustrating a configuration of relevant parts of a semiconductor device according to an embodiment;

FIG. 2 is a partially enlarged sectional view of a semiconductor element;

FIG. 3 is a sectional view illustrating a formation process of a via portion;

FIG. 4 is a sectional view illustrating a formation process of a metal film and a barrier metal layer;

FIG. 5 is a sectional view illustrating an etching process of the metal film;

FIG. 6 is a sectional view illustrating a film-formation process of an interlayer dielectric film;

FIG. 7 is a sectional view illustrating a formation process of the via portion;

FIG. 8 is a sectional view illustrating a formation process of a metal layer;

FIG. 9 is a partially enlarged sectional view of a bonded area between a memory chip and a circuit chip; and

FIG. 10 is a diagram illustrating a relation between an annealing temperature for pad bonding and a coefficient of thermal expansion.

### DETAILED DESCRIPTION

Embodiments will now be explained with reference to the accompanying drawings. The present invention is not limited to the embodiments.

A semiconductor device according to an embodiment comprises a first chip including a first semiconductor substrate, a first semiconductor element provided on the first semiconductor substrate, a first wiring layer to be connected to the first semiconductor element, and a first pad to be connected to the first wiring layer, and a second chip including a second semiconductor substrate, a second semiconductor element provided on the second semiconductor substrate, a second wiring layer to be connected to the second semiconductor element, and a second pad to be connected to the second wiring layer and joined to the first pad. At least one of the first pad and the second pad includes a first metal layer to be joined to the other pad, a second metal layer having a coefficient of thermal expansion higher than that of the first metal layer, and a barrier metal layer provided between the first metal layer and the second metal layer.

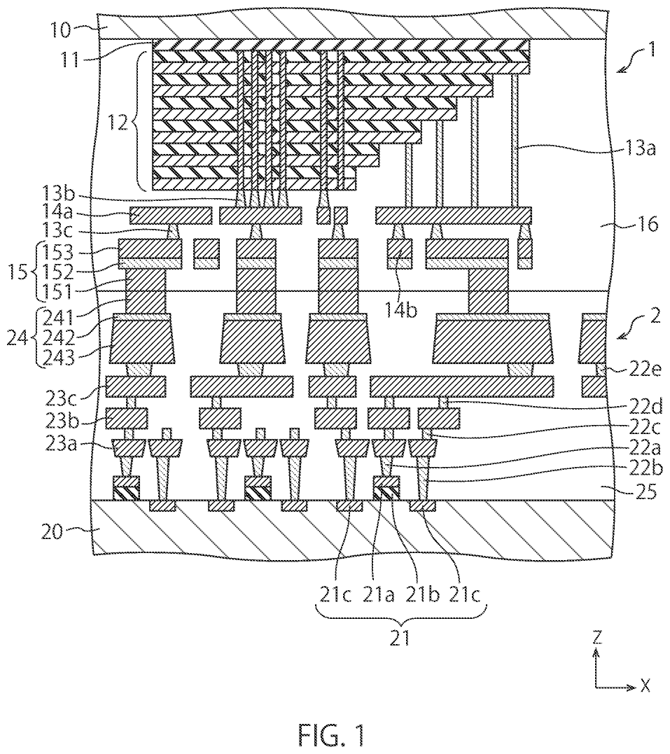

FIG. 1 is a sectional view illustrating a configuration of relevant parts of the semiconductor device according to the embodiment.

The semiconductor device according to the present embodiment is a three-dimensional semiconductor memory formed by bonding a memory chip 1 (first chip) and a circuit chip 2 (second chip) to each other. First, a configuration of the memory chip 1 is described. The memory chip 1 includes a semiconductor substrate 10, an insulating layer 11, a semiconductor element 12 (first semiconductor element), contact plugs 13a to 13c, wiring layers 14a and 14b, pads 15 (first pads), and an interlayer dielectric film 16.

The semiconductor substrate 10 is a silicon substrate, for example. The insulating layer 11 is provided on the semiconductor substrate 10. The insulating layer 11 is a silicon oxide layer or a silicon nitride layer, for example. The semiconductor element 12 is provided on the insulating layer 11.

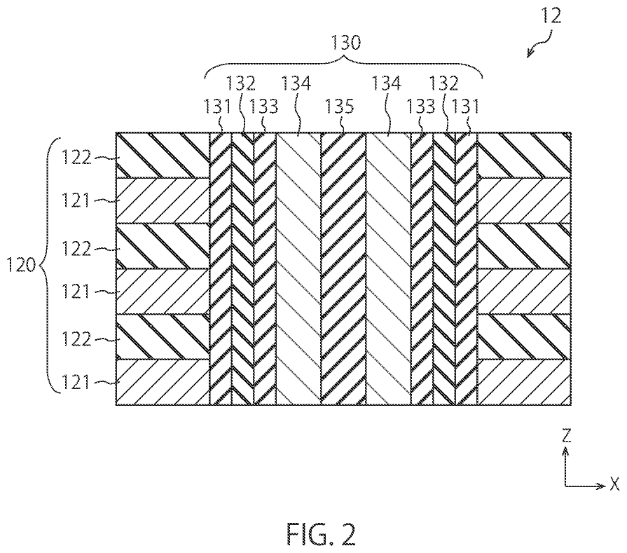

FIG. 2 is a partially enlarged sectional view of the semiconductor element 12. As illustrated in FIG. 2, the semiconductor element 12 includes a laminated body 120 and a memory film 130.

In the laminated body 120, a plurality of electrode layers 121 and a plurality of insulating layers 122 are alternately laminated in a Z direction orthogonal to the semiconductor substrate 10. Each electrode layer 121 is a metal layer of, for example, tungsten or the like, and is a word line of the memory film 130. Each insulating layer 122 is a silicon oxide layer, for example. An end portion of the laminated body 120 is formed in a stepwise manner as illustrated in FIG. 1. In the stepwise end portion, each electrode layer 121 is connected to the wiring layer 14a through the contact plug 13a.

As illustrated in FIG. 2, the memory film 130 penetrates the laminated body 120 in the Z direction, and includes block insulating films 131, charge accumulation layers 132, tunnel insulating films 133, channel layers 134, and a core insulating film 135. The charge accumulation layers 132 are silicon nitride films, for example, and are formed on side surfaces of the electrode layers 121 and the insulating layers 122 through the block insulating films 131. The block insulating films 131, the tunnel insulating films 133, and the core insulating film 135 are silicon oxide films, for example. The channel layers 134 are silicon layers, for example, and are formed on side surfaces of the charge accumulation layers 132 through the tunnel insulating films 133. The channel layers 134 are connected to the wiring layer 14a through the contact plugs 13b (see FIG. 1).

As illustrated in FIG. 1, the wiring layer 14a is connected to the pad 15 or the wiring layer 14b through the contact plug 13c. As the material of the contact plugs 13a to 13c and the wiring layers 14a and 14b, for example, aluminum and copper can be used. When the metal material differs between the contact plugs 13a to 13c and the wiring layers 14a and 14b, it is preferable that a barrier metal layer is formed between these elements to prevent metallic diffusion.

In FIG. 1, a portion of the wiring layers 14a and 14b is illustrated integrally in a simplified manner; however, in practice, these elements are formed of a plurality of wirings insulated and isolated by the interlayer dielectric film 16.

The pad 15 includes a metal layer 151 (first metal layer), a barrier metal layer 152, and a metal layer 153 (second metal layer). The metal layer 151 is joined to the circuit chip 2. The barrier metal layer 152 is provided between the metal layer 151 and the metal layer 153. Diffusion of the metal layer 151 can be prevented by the barrier metal layer 152. The metal layer 153 is provided in the same layer as the wiring layer 14b.

In the present embodiment, the material of the metal layer 151 is copper, the material of the metal layer 153 is aluminum, and the material of the barrier metal layer 152 is titanium nitride. The materials of the metal layer 151 and the metal layer 153 are not particularly limited to any specific one as long as these layers satisfy a relationship in which the coefficient (amount) of thermal expansion of the metal layer 153 is higher than the coefficient of thermal expansion of the metal layer 151.

Next, a configuration of the circuit chip 2 is described. As illustrated in FIG. 1, the circuit chip 2 includes a substrate 20, a semiconductor element 21 (second semiconductor element), contact plugs 22a to 22e, wiring layers 23a to 23c, pads 24 (second pads), and an interlayer dielectric film 25.

The substrate 20 is a silicon substrate, for example. On the substrate 20, a semiconductor element 21 that drives the memory chip 1 is provided.

The semiconductor element 21 is a MOSFET (Metal-Oxide-Semiconductor Field Effect Transistor) including a gate electrode 21a, a gate dielectric film 21b, and diffusion layers 21c. The diffusion layer 21c is a source region or a drain region. The gate electrode 21a is provided on the gate dielectric film 21b, and connected to the wiring layer 23a through the contact plug 22a. The diffusion layers 21c are connected to the wiring layer 23a through the contact plugs 22b.

The wiring layer 23a is connected to the wiring layer 23b through the contact plugs 22c. The wiring layer 23b is connected to the wiring layer 23c through the contact plugs 22d. The wiring layer 23c is connected to the pads 24 through the contact plugs 22e.

In the present embodiment, as the material of the contact plugs 22a to 22e and the wiring layers 23a to 23c, for example, aluminum, copper, and the like can be used. When the metal material differs between the contact plugs 22a to 22e and the wiring layers 23a to 23c, it is preferable that a barrier metal layer is formed between these elements to prevent metallic diffusion.

In FIG. 1, a portion of the wiring layers 23a to 23c is illustrated integrally in a simplified manner; however, in practice, these elements are formed of a plurality of wirings insulated and isolated by the interlayer dielectric film 25.

The pad 24 includes a metal layer 241 (first metal layer), a barrier metal layer 242, and a metal layer 243 (second metal layer). The metal layer 241 is joined to the metal layer 151 of the memory chip 1. The barrier metal layer 242 is provided between the metal layer 241 and the metal layer 243. Diffusion of the metal layer 241 can be prevented by the barrier metal layer 242. The metal layer 243 is connected to the contact plugs 22e. Although not illustrated in FIG. 1, the circuit chip 2 may have a wiring layer positioned in the same layer as the metal layer 243.

In the present embodiment, the material of the metal layer 241 is copper, the material of the metal layer 243 is aluminum, and the material of the barrier metal layer 242 is titanium nitride. The materials of the metal layer 241 and the metal layer 243 are not particularly limited to any specific one as long as these layers satisfy a relationship in which the coefficient of thermal expansion of the metal layer 243 is higher than the coefficient of thermal expansion of the metal layer 241.

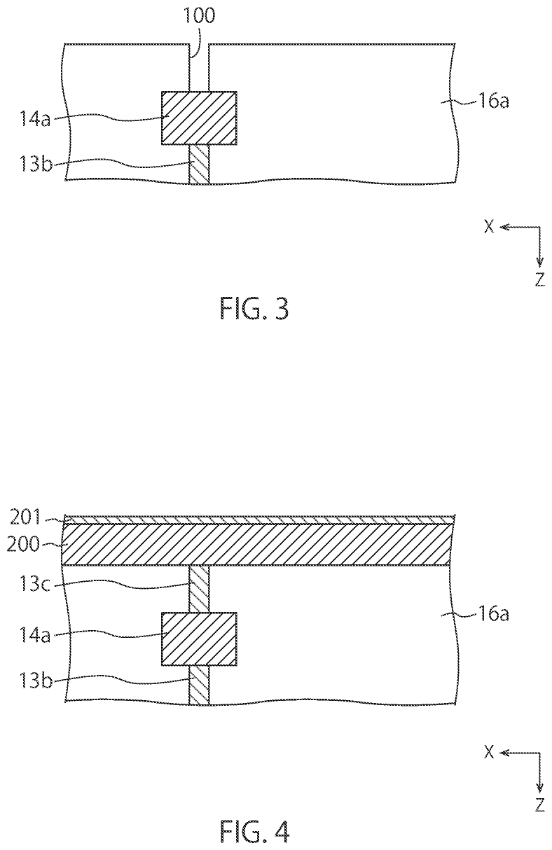

In the following explanations, a part of a manufacturing process of the semiconductor device configured as described above is described. A manufacturing process of the pad 15 is described here with reference to FIGS. 3 to 8. The same manufacturing process as that for the pad 15 can be employed for the pad 24.

First, as illustrated in FIG. 3, a via portion 100 is formed in the interlayer dielectric film 16a covering the wiring layer 14a. The via portion 100 reaches the wiring layer 14a.

Next, as illustrated in FIG. 4, a metal film 200 is formed on an upper surface of the interlayer dielectric film 16a, and a barrier metal layer 201 is further formed on this metal film 200. The material of the metal film 200 is aluminum, and this aluminum is also embedded within the via portion 100. Aluminum embedded in the via portion 100 is the contact plug 13c.

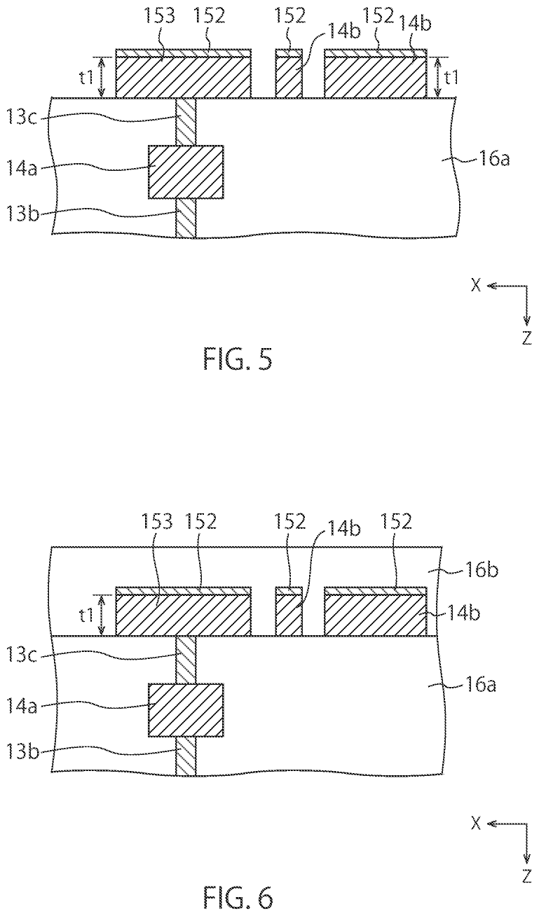

Next, as illustrated in FIG. 5, the metal film 200 and the barrier metal layer 201 are etched by RIE (Reactive Ion Etching), for example. Accordingly, the metal layer 153 and the wiring layer 14b having a same thickness t1 are patterned in the same layer at the same time. Simultaneously, a barrier metal layer 152 is also patterned on the metal layer 153 and the wiring layer 14b. A portion of wiring belonging to the wiring layer 14b can be used as a bonding pad, for example. This bonding pad is joined to a bonding wire (not illustrated) for connecting the circuit chip 2 to another mounting substrate or the like.

Next, as illustrated in FIG. 6, the interlayer dielectric film 16b is formed on the interlayer dielectric film 16a so as to cover the metal layer 153, the wiring layer 14b, and the barrier metal layer 152. The interlayer dielectric film 16b can be formed by, for example, CVD (Chemical Vapor Deposition) and CMP (Chemical Mechanical Polishing).

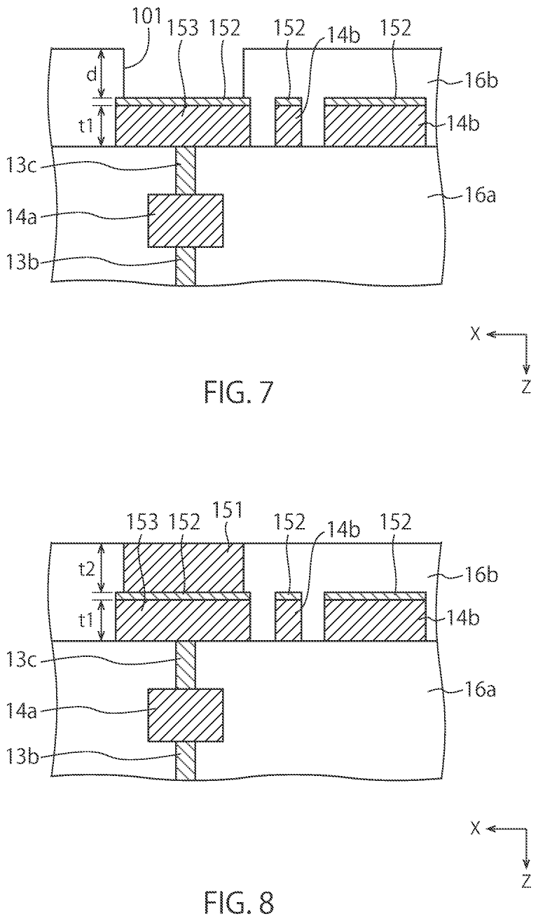

Next, as illustrated in FIG. 7, a hole portion 101 is formed in the interlayer dielectric film 16b. In the present embodiment, an opening area of the hole portion 101 is narrower than a plane area of the metal layer 153. A depth d of the hole portion 101 is equal to the thickness t1 of the metal layer 153.

Next, as illustrated in FIG. 8, by embedding copper in the hole portion 101, the metal layer 151 is formed. As described above, the depth d of the hole portion 101 is equal to the thickness t1 of the metal layer 153, so that a thickness t2 of the metal layer 151 is equal to the thickness t1 of the metal layer 153. Thereafter, the memory chip 1 is flipped vertically (rotated 180 degrees) and bonded to the circuit chip 2.

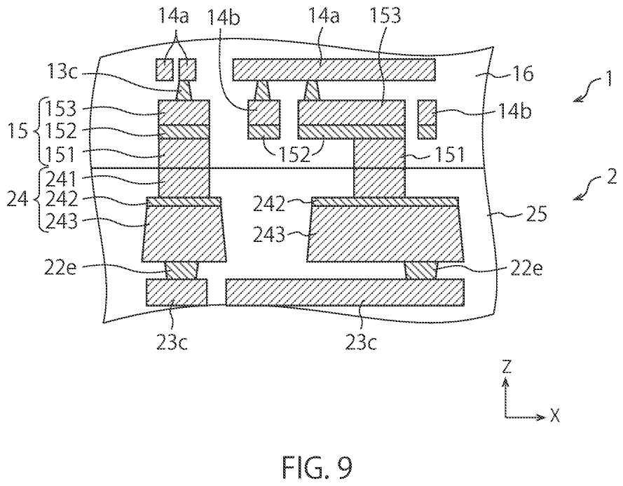

FIG. 9 is a partially enlarged sectional view of a bonded area between the memory chip 1 and the circuit chip 2. As illustrated in FIG. 9, the metal layer 151 of the pad 15 and the metal layer 241 of the pad 24 are joined to each other. The pad 15 includes the metal layer 153 with a coefficient of thermal expansion higher than that of the metal layer 151, and the pad 24 includes the metal layer 243 with a coefficient of thermal expansion higher than that of the metal layer 241.

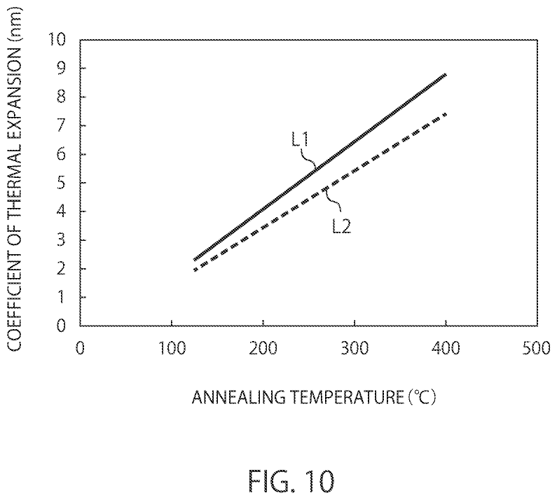

FIG. 10 is a diagram illustrating a relationship between an annealing temperature for pad bonding and a coefficient of thermal expansion. In FIG. 10, a solid line L1 represents a coefficient of thermal expansion of the pad 15 according to the present embodiment. Specifically, the material of the metal layer 151 is copper, the material of the metal layer 153 is aluminum, and the thicknesses of the respective layers are 600 nanometers. Meanwhile, a dotted line L2 represents a coefficient of thermal expansion of a pad according to a comparative example. The material of this pad is copper, and the thickness thereof is 1200 nanometers.

As illustrated in FIG. 10, at each annealing temperature, the coefficient of thermal expansion of the pad 15 according to the present embodiment is larger than the coefficient of thermal expansion of the pad according to the comparative example. Therefore, even when the annealing temperature is low at the time of bonding of the pad 15 and the pad 24, shortage in thermal expansion of the metal layer 151 and the metal layer 241 can be compensated by the thermal expansion of the metal layer 153 and the metal layer 243.

Therefore, according to the present embodiment, the metal layer 151 and the metal layer 241 can be joined to each other without any space therebetween, so that bonding defects can be avoided.

In addition, in the present embodiment, the metal layer 151 and the metal layer 153 are connected without a contact plug therebetween. Similarly, the metal layer 241 and the metal layer 243 are connected without a contact plug therebetween. Therefore, when the annealing temperature is high, a problem in which a metal material (copper) contained in the contact plug is soaked up to the metal layers 151 and 241 can also be avoided.

In the present embodiment, both of the pad 15 and the pad 24 include two metal layers with different coefficients of thermal expansion. However, either the pad 15 or the pad 24 may include the two metal layers. That is, it suffices that at least one of the pad 15 and the pad 24 includes a first metal layer to be joined to the other pad, a second metal layer having a coefficient of thermal expansion higher than that of the first metal layer, and a barrier metal layer provided between the first metal layer and the second metal layer. Also in this case, by compensating shortage in the coefficient of thermal expansion of the first metal layer with the second metal layer, joining defects between the pad 15 and the pad 24 can be avoided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a first chip including a first semiconductor substrate, a first semiconductor element provided on the first semiconductor substrate, a first wiring layer to be connected to the first semiconductor element, and a first pad to be connected to the first wiring layer; and
a second chip including a second semiconductor substrate, a second semiconductor element provided on the second semiconductor substrate, a second wiring layer to be connected to the second semiconductor element, and a second pad to be connected to the second wiring layer and joined to the first pad, wherein
at least one of the first pad and the second pad includes a first metal layer to be joined to the other pad, a second metal layer having a coefficient of thermal expansion higher than that of the first metal layer, and a barrier metal layer provided between the first metal layer and the second metal layer.

2. The device of claim 1, wherein a plane area of the second metal layer is larger than a plane area of the first metal layer.

3. The device of claim 1, wherein the second metal layer contains aluminum.

4. The device of claim 1, wherein the first metal layer contains copper.

5. The device of claim 1, further comprising a contact plug made of a same material as the second metal layer and provided between the first wiring layer or the second wiring layer and the second metal layer.

6. The device of claim 1, wherein the second metal layer is provided in a same layer as a wiring belonging to the first wiring layer or the second wiring layer.

7. The device of claim 1, wherein a thickness of the first metal layer is same as a thickness of the second metal layer.

8. A manufacturing method of a semiconductor device, comprising:
forming, in a first chip, a first semiconductor substrate, a first semiconductor element provided on the first semiconductor substrate, a first wiring layer to be connected to the first semiconductor element, and a first pad to be connected to the first wiring layer;
forming a second semiconductor substrate, a second semiconductor element provided on the second semiconductor substrate, a second wiring layer to be connected to the second semiconductor element, and a second pad to be connected to the second wiring layer; and
joining the first pad and the second pad to each other, wherein
in at least one of the first pad and the second pad, a first metal layer to be joined to the other pad, a second metal layer having a coefficient of thermal expansion higher than that of the first metal layer, and a barrier metal layer provided between the first metal layer and the second metal layer, are formed.

9. The method of claim 8, wherein on the second metal layer, a hole portion having an opening area narrower than a plane area of the second metal layer is formed, and the first metal layer is formed in the hole portion.

10. The method of claim 8, wherein the second metal layer is formed by using aluminum.

11. The method of claim 8, wherein the first metal layer is formed by using copper.

12. The method of claim 8, wherein a contact plug made of a same material as the second metal layer is formed between the first wiring layer or the second wiring layer and the second metal layer.

13. The method of claim 8, wherein in a same layer as a wiring belonging to the first wiring layer or the second wiring layer, the second metal layer is formed at a same time with the wiring.

14. The method of claim 8, wherein a thickness of the first metal layer and a thickness of the second metal layer are formed to be same as each other.
